(19) United States
(12) Patent Application Publication
(10) Pub. No.: US 2018/0037001 A1
(43) Pub. Date: Feb. 8, 2018

(54) HEAT DIFFUSION SHEET

(71) Applicant: DEXERIALS CORPORATION, Tokyo (JP)

(72) Inventors: Minoru NAGASHIMA, Tokyo (JP); Teruo HIYAMA, Tokyo (JP)

(73) Assignee: DEXERIALS CORPORATION, Tokyo (JP)

(21) Appl. No.: 15/722,762

(22) Filed: Oct. 2, 2017

Related U.S. Application Data
(63) Continuation of application No. PCT/JP2016/060664, filed on Mar. 31, 2016.

(30) Foreign Application Priority Data
Mar. 31, 2015 (JP) 2015-073547

(51) Int. Cl. B32B 9/04; H01L 51/00; H01L 23/373; H01L 51/52; B32B 7/12; B32B 27/36

(52) U.S. Cl. CPC B32B 9/04; B32B 7/12; B32B 27/36; H01L 23/3735; H01L 51/529; H01L 51/004; H01L 51/0034; B32B 2309/105; B32B 2307/30; H01L 23/3737

(57) ABSTRACT

A heat diffusion sheet includes a graphite sheet having a thickness of from 20 μm to 80 μm, an acrylic adhesive layer having a thickness within a range of from 5 μm to 15 μm and not containing a thermally conductive material, a polyester film having a thickness within a range of from 5 μm to 30 μm, and a silicone adhesive layer thinner than the polyester film, having a thickness within a range of from 2 μm to 25 μm, not containing a thermally conductive material and having a peeling strength of from 0.005 N/cm to 1.0 N/cm, sequentially laminated from the graphite sheet. Heat generated by the object to which the silicone adhesive layer is to be adhered is easily transferred to the graphite sheet and the heat diffusion sheet can be peeled off and reused easily.

This application is a continuation of International Application No. PCT/JP2016/060664, filed on Mar. 31, 2016, which claims priority to Japan Patent Application No. 2015-073547, filed on Mar. 31, 2015. The contents of the prior applications are herein incorporated by reference in their entireties.

### TECHNICAL FIELD

The present disclosure generally relates to a heat diffusion sheet used for heat radiation and particularly to a heat diffusion sheet for diffusing heat in a spreading direction of the heat diffusion sheet.

### BACKGROUND ART

Recently, performance improvement of electronic devices, such as, a personal computer, a mobile phone, and a PDA is remarkable and this has been realized by remarkable performance improvement of a CPU. With such performance improvement of the CPU, a heat generation amount of the CPU has remarkably increased, and how to radiate heat in the electronic device has become an important problem.

Counter Measures against heat include an air cooling method by a fan and a liquid cooling method by using a heat pipe and water, but they both need a new device for heat radiation, and not only a weight increase of the device but also an increase of a noise or increase of an electricity usage amount, which is a defect.

On the other hand, a method of diffusing heat generated by the CPU as rapidly as possible and to as wide an area as possible has an object to improve cooling efficiency, and is the most realistic cooling method in the electronic devices, such as, a mobile phone and a personal computer.

Incidentally, in a display device represented by an organic EL element, a size increase has been promoted in recent years, and accuracy and in particularly, uniformity of the device is given importance. Particularly in the organic EL element, because an element itself is constituted by an organic substance, deterioration caused by heat is known to affect the life of the element, particularly light emitting characteristics and a color change, and it sometimes involves change-with-time by heat generated by a driving circuit constituting the device and the like.

As a thermal conduction sheet used for such heat radiation purposes, a sheet-shaped graphite has attracted great attention in recent years.

That is because a high-quality graphite sheet has extremely high thermal conductivity of at least 100 W/(m·K) and at most 1000 W/(m·K), and has extremely high performances as compared with characteristics of thermal conductivity of the other gel-state heat radiation material or a sheet-shaped heat radiation material, so that it is optimal for diffusing the heat.

Patent reference 1 describes a thermal conductive sheet for directly transferring heat from a heat generating body to a heat radiating member, and Patent reference 2 and Patent reference 3 describe a heat diffusion type thermal conductive sheet for diffusing the heat from the heat generating body in a planar direction.

As the thermal conductive sheet, not the one in Patent reference 1 but the thermal conductive sheets described in Patent reference 2 and Patent reference 3 have attracted attention. Particularly, a so-called graphite sheet obtained by making graphite into a sheet-shaped has attracted attention.

That is, the graphite sheet has high thermal conductivity of at least 100 W/(m·K) and at most 1000 W/(m·K) in the planar direction. By diffusing the heat from the heat generating body and by unifying a temperature in the electronic device, functional deterioration of components arranged in the device is prevented.

In Embodiment 3 (the paragraph 0048) of Patent reference 2 here has been disclosed a technology of adhering a double-sided tape having an adhesive layer formed on both surfaces of abase material, such as, a PET film on one surface of the graphite sheet in advance, and adhering the graphite sheet on a surface of an electronic device to be adhered (hereinafter referred to as a surface to be adhered) by the adhesive layer, but the adhesive layer does not usually have thermal conductivity and tends to lower a heat diffusion effect of the entire sheet. Moreover, in an acrylic adhesive layer normally used as an adhesive layer, it is difficult to peel off the graphite sheet for re-adhering.

Thus, in Patent reference 3, it is attempted to prevent deterioration of the thermal conductivity and to facilitate peeling-off for re-adhering by providing a graphite sheet (claim 1) in which a thermally conductive material is contained in an elastic layer (corresponding to the adhesive layer) such as a silicone rubber on one surface of the graphite sheet.

However, in an image panel or particularly an image display panel, such as, an OLED panel (organic EL panel), a surface constituting the panel is glass and extremely smooth, but when the thermally conductive material is contained in the adhesive layer, roughness is formed on the surface of the adhesive layer and it causes nonconformity that initial adhesiveness lowers. This lowering of the adhesiveness contributes to facilitation of peeling-off, but because a rate of a resin component relatively constituting the adhesive layer lowers, deterioration of adhesion reliability cannot be avoided (problem 1).

Moreover, when a thickness of the graphite sheet is 300 μm or less, it does not make a big problem; but if the thickness of the graphite sheet becomes larger than that, rigidity of the entire sheet rises and as a result, it becomes difficult to bend the sheet in peeling-off. Thus, when the graphite sheet is to be peeled off the surface on which the graphite sheet is adhered, the graphite sheet is pulled toward an upper side in such a manner that an angle formed by the graphite sheet and the surface does not become large, but in that case, the silicone adhesive layer can be easily coagulated and destroyed, and as a result, it can easily remain on the surface to be adhered (problem 2).

### CITATION LIST

### Patent Literature

Patent reference 1: Japanese Patent Laid-Open publication No. 2007-180281
Patent reference 2: Japanese Patent Laid-Open publication No. 2008-060527
Patent reference 3: Japanese Patent Laid-Open publication No. 2007-012913

### SUMMARY

### Technical Problem

In order to solve the aforementioned problems, an object of the present disclosure is to provide a re-peelable heat diffusion sheet that can efficiently transmit heat generated by an element or a device while excellent thermal conductivity is sufficiently ensured.

Furthermore, an object of the present disclosure is to provide a heat diffusion sheet having high adhesion reliability.

Moreover, an object of the present disclosure is to provide a heat diffusion sheet capable of being peeled off without coagulation and destruction of a silicone adhesive layer.

### Solution to Problem

In order to achieve the aforementioned objects, an embodiment according to the present disclosure is a heat diffusion sheet including a graphite sheet and a composite adhesive film arranged on a surface of the graphite sheet, wherein a thickness of the graphite sheet is at least_20 μm and less than 80 μm; a thickness of the composite adhesive film is within a range of at least 20 μm and at most 100 μm; and the composite adhesive film has: an acrylic adhesive layer arranged on the graphite sheet and not containing a thermally conductive material; a polyester film arranged on the acrylic adhesive layer and having a thickness within a range at least of 5 μm and at most 30 μm; and a silicone adhesive layer arranged on the polyester film, thinner than the polyester film, having a thickness within a range of at least 2 μm and at most 25 μm, not containing a thermally conductive material, and having a peeling strength of 0.005 N/cm or more and 1.0 N/cm or less.

Furthermore, the present invention is a heat diffusion sheet including a graphite sheet, and a composite adhesive film arranged on a surface of the graphite sheet, wherein a thickness of the graphite sheet is in a range of at least 20 μm and less than 80 μm. The composite adhesive film includes an acrylic adhesive layer arranged on the graphite sheet and not containing a thermally conductive material, and having a thickness within a range of at least 5 μm and at most 15 μm, a polyester film arranged on the acrylic adhesive layer and having a thickness within a range of at least 5 μm and at most 30 μm, and a silicone adhesive layer arranged on the polyester film, thinner than the polyester film, having a thickness within a range of at least 2 μm and at most 25 μm, not containing a thermally conductive material, and having a peeling strength of at least 0.005 N/cm and at most 1.0 N/cm, and wherein a total value of a thickness of the acrylic adhesive layer, the thickness of the polyester film and the thickness of the silicone adhesive layer is within a range of at least 12 μm and at most 70 μm.

### Advantageous Effects

As described above, an embodiment of the present disclosure is a heat diffusion sheet using a composite adhesive film having a composite adhesive layer with respect to a graphite sheet. In such a heat diffusion sheet, first, use of the graphite sheet provides an excellent thermal conductivity in a spreading direction, heat generated from a heat generating element is transferred in the spreading direction of the heat diffusion sheet, then, the heat diffusion sheet becomes a uniform temperature, and even if an object to be adhered on which the heat diffusion sheet is adhered partially generates heat, an effect of uniform temperature rise is exerted.

Furthermore, one surface of the silicone adhesive layer is firmly adhered to the polyester film, while the other surface is given an adhesive force peelable from the object to be adhered such as a glass plate, and thus, the heat diffusion sheet can be reused after it is peeled off the object to be adhered.

Although the thermal conductivity of the composite adhesive film is low, it is formed having a small thickness, and heat resistance of the composite adhesive film in a film thickness direction is made small, and thus, heat generated from the object to be adhered can be easily transferred to the graphite sheet.

### BRIEF DESCRIPTION OF THE DRAWING

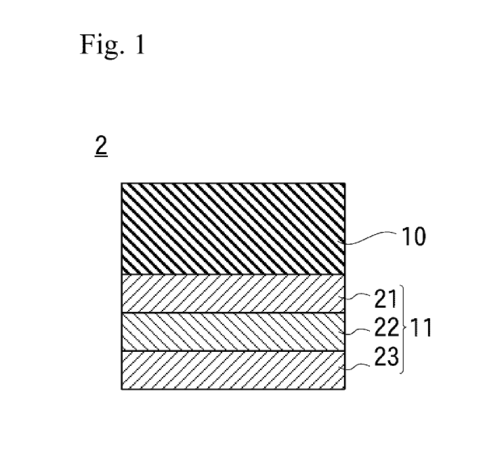

The FIG. 1 is a diagram for explaining a heat diffusion sheet of the present disclosure.

### DESCRIPTION OF EMBODIMENTS

An embodiment of the present disclosure will be described in the order of the following items:

1. Heat diffusion sheet (graphite sheet with adhesive) of the present disclosure;
2. Graphite sheet;
3. Composite adhesive film;
4. Acrylic adhesive layer;
5. Polyester film;
6. Silicone adhesive layer;
7. Relationship between polyester film and silicone adhesive layer; and
8. Manufacturing method of graphite sheet having adhesive.

### <1. Graphite Sheet Having Adhesive of the Present Disclosure>

Reference numeral 2 in the FIGURE denotes a heat diffusion sheet of the present disclosure and has a graphite sheet 10 and a composite adhesive film 11.

This heat diffusion sheet 2 is adhered to an inside and a portion of a device, such as, a display device represented by an organic EL element and plays a role of diffusing heat from its heat source.

### <2. Graphite Sheet>

The graphite sheet 10 used in the present disclosure is manufactured mainly from natural graphite, has high thermal conductivity, and has a characteristic that a thickness can be arbitrarily adjusted from several tens micron to several thousands micron.

The graphite sheet 10 used in the present disclosure has anisotropy in thermal conductivity due to its crystallinity such that the thermal conductivity in a thickness direction is low, and heat is difficult to transfer easily, while the thermal conductivity in a spreading direction (direction in parallel to a surface of the sheet) is high and the heat can be easily transferred. The thermal conductivity in the spreading direction has a magnitude of several times of copper or aluminum, and the graphite sheet 10 is lighter than a metal sheet.

The thickness of the graphite sheet is usually within a range of at least 50 μm and at most 2000 μm, but in the case of the graphite sheet 10 used in the heat diffusion sheet 2 of the present disclosure, for its purpose of usage in a device requiring thinning, such as, an image panel of an OLED, or in order to handle nonconformity that flexibility of the sheet itself is lost and wrinkles can easily occur, the thickness is preferably less than 80 μm. Then, the composite adhesive film 11 of the present disclosure is suitable for thinning in the case where the thickness of the graphite sheet 10 is at least 20 μm or particularly it is at least 30 μm as will be described later, and occurrence of wrinkles is also prevented.

Note that the thermal conductivity of the graphite sheet 10 is at least 200 W/(m·K) and at most 2000 W/(m·K), and its thermal conductivity is affected by orientation of the graphite, a molecular weight, rolling density or the like.

### <3. Composite Adhesive Film>

The composite adhesive film 11 of the present disclosure is formed on one surface of the aforementioned graphite sheet 10 and has a role of adhering the graphite sheet 10 onto the surface of the object to be adhered.

Furthermore, because the composite adhesive film 11 does not contain a thermally conductive material as will be described later, the thermal conductivity of the entire composite adhesive film 11 is within a range of at least 0.05 W/(m·K) and at most 0.5 W/(m·K).

Therefore, in order to prevent the damage of the thermal conductivity of the graphite sheet 10, and also in order not to give an influence on the other effects of the present disclosure, a total thickness of the composite adhesive film 11 is preferably set within a range of at least 20 μm and at most 100 μm, or particularly within a range of at least 22 μm and at most 55 μm.

The composite adhesive film 11 is constituted such that an acrylic adhesive layer 21 is provided on one surface of a polyester film 22, while a silicone adhesive layer 23 is provided on a surface on a side opposite to the one surface, and the heat diffusion sheet 2 is constituted such that a surface of the acrylic adhesive layer 21 is brought into contact with a surface of the graphite sheet 10, and the graphite sheet 10 and the composite adhesive film 11 are adhered to each other.

### <4. Acrylic Adhesive Layer>

A material constituting the acrylic adhesive layer 21 includes an acrylic copolymer (a) that becomes a base polymer, a tackifier (b) that is compatible with the base polymer so as to develop adhesiveness, and a hardening agent (c) for adjusting a coagulation force of the acrylic copolymer (a), and before the acrylic adhesive layer 21 is brought into contact with the graphite sheet 10, a reaction between the acrylic copolymer (a) and the hardening agent (c) is finished, although it is not complete.

As the acrylic copolymer (a), an acrylic copolymer can be used which is selected from monomers made of acrylic acid, methacrylic acid, 2-hydroxyethyl or propyl acrylate, 2-hydroxypropyl methacrylate, N-methylolacrylamide, N-methylolmethacrylamide, acryl or methacrylamide and the like in addition to a monomer having a functional group such as a methacryloyl group, a hydroxyl group, a carboxyl group, a methylol group, or an amide group, such as 2-hydroxyethyl methacrylate, for example. Moreover, as the tackifier (b), a low-molecular polymer can be used which is made of a phenol resin, a terpene resin, a rosin resin, a hydrogenated rosin resin, a xylene resin or an acrylic resin.

As the hardening agent (c), when a monomer having a hydroxyl group as a component of the acrylic copolymer (a) or the like is contained, an isocyanate hardening agent or the like can be used, while when a monomer having a functional group, such as, epoxy is contained, an ethylene imine hardening agent or the like can be used.

A thickness of the acrylic adhesive layer 21 is at least 5 μm and at most 15 μm, and particularly at most 10 μm. If the thickness is smaller than 5 μm, such nonconformity occurs that tackiness with the object to be adhered is insufficient, while if it is larger than 15 μm, such nonconformity occurs that heat resistance rises and favorable thermal conductivity cannot be obtained, although it depends on a thickness of the polyester film 22. In a case of 10 μm or less, the heat resistance further lowers.

Note that a thermally conductive material is not contained similarly to the silicone adhesive layer 23 that will be described later.

### <5. Polyester Film>

The polyester film 22 can generate strength of the entire composite adhesive film 11 and has a role of facilitating peeling-off in terms of a relationship with the thickness of the silicone adhesive layer 23 that will be described later.

Moreover, it also plays a role of preventing mixing of the acrylic adhesive layer 21 and the silicone adhesive layer 23 when the both layers are to be directly laminated.

For the polyester film 22, polyethylene terephthalate (PET) can be suitably used, and its thickness is preferably within a range of at least 5 μm and at most 30 μm, and particularly at least 10 μm, and also is preferably within a range of at most 25 μm. When a PET film subjected to biaxial stretching processing is used, a tensile strength is preferably within a range of at least 100 MPa and at most 300 MPa in a vertical stretching direction and is preferably within a range of at least 10 MPa and at most 50 MPa in a lateral stretching direction.

Furthermore, a storage elastic modulus is preferably within a range of 1000 Pa or more and 10000 MPa or less.

### <6. Silicone Adhesive Layer>

The silicone adhesive layer 23 is made of an additional reaction type silicone resin and is selected from a viewpoint that an adhesive force (peeling strength) to an image panel (glass) such as OLED becomes at least 0.005 N/cm and at most 1.0 N/cm. Specifically, organosiloxane such as dimethyl siloxane can be used.

Note that, as described above, since the composite adhesive film 11 has its strength improved by the polyester film 22, the present disclosure does not have to form the silicone adhesive layer 23 with a large thickness and specifically, the thickness of the silicone adhesive layer 23 is preferably 2 μm or more or particularly 5 μm or more since tackiness is needed, and from a viewpoint of favorable detachability, the thickness is preferably 25 μm or less or particularly 20 μm or less.

Moreover, the silicone adhesive layer 23 does not contain a thermally conductive material similarly to the aforementioned acrylic adhesive layer 21.

### <7. Relationship Between Polyester Film and Silicone Adhesive Layer>

The polyester film 22 and the silicone adhesive layer 23 regulate detachability unlike the acrylic adhesive layer 21 but the thickness relationship is preferably changed in accordance with the thickness or a desired area of the graphite sheet 10.

For example, when the thickness of the graphite sheet 10 is 50 μm or more and less than 80 μm, and its area is relatively small, such as, at least 25 cm² and at most 300 cm² (12 cm×6.7 cm, for example), the thickness of the polyester film 22 is preferably set within a range of at least 10 μm and at most 20 μm, and the thickness of the silicone adhesive layer 23 is preferably smaller than the thickness of the polyester film 22 and in the range of at least 5 μm and at most 10 μm.

That is, the thickness of the polyester film 22 to the thickness of the silicone adhesive layer 23 is preferably set larger within a range of at least 1.0 time and at most 4.0 times.

Moreover, if an area of the graphite sheet 10 is relatively large such as at least 4000 cm² and at most 15000 cm² (121.7 cm×68.5 cm, for example), the thickness of the polyester film 22 is preferably set to at least 20 μm and at most 30 μm, and the thickness of the silicone adhesive layer 23 is preferably set to 10 μm or more to 25 μm or less under a condition smaller than the thickness of the polyester film 22. That is, the thickness of the polyester film 22 to the thickness of the silicone adhesive layer 23 is preferably at least 1.0 time and at most 3.0 times.

### <8. Manufacturing Method of Graphite Sheet Having Adhesive>

A manufacturing method of a graphite sheet with an adhesive of the present disclosure is in a manner such that the graphite sheet 10 described above is prepared, the acrylic adhesive layer 21, the polyester film 22, and the silicone adhesive layer 23 may be sequentially formed on the graphite sheet 10, or the heat diffusion sheet (graphite sheet having an adhesive) 2 of the present disclosure may be manufactured such that there is prepared the composite adhesive film 11 that is a double-sided composite adhesive sheet in which the acrylic adhesive layer 21 in contact with the polyester film 22 is formed on the one surface of the polyester film 22, while the silicone adhesive layer 23 in contact with the polyester film 22 is formed on the other surface, the acrylic adhesive layer 21 side of the composite adhesive film 11 and the graphite sheet 10 are brought into contact with each other, and the composite adhesive film 11 is adhered to the graphite sheet 10.

Moreover, the heat diffusion sheet 2 of the present disclosure may be manufactured such that an intermediate sheet A in which the silicone adhesive layer 23 is formed on the polyester film 22 is formed, while an intermediate sheet B in which the acrylic adhesive layer 21 is formed on a separation film, and a surface of the polyester film 22 of the intermediate sheet A and a surface of the acrylic adhesive layer 21 of the intermediate sheet B are brought into contact with each other, and the intermediate sheet A and the intermediate sheet B are adhered together so as to fabricate the composite adhesive film 11 that is a double-sided adhesive sheet, the separation films on the acrylic adhesive layer 21 side are removed, the surface of the exposed acrylic adhesive layer 21 is brought into contact with the surface of the graphite sheet 10, and the composite adhesive film 11 is adhered to the graphite sheet 10.

Moreover, the heat diffusion sheet 2 of the present disclosure may be manufactured such that the intermediate sheet A in which the silicone adhesive layer 23 is provided on the polyester film 22, and an intermediate sheet C in which the acrylic adhesive layer 21 is provided by applying a material of the acrylic adhesive layer 21 on the graphite sheet 10 are prepared, the surface of the polyester film 22 of the intermediate sheet A is exposed, and the surface of the acrylic adhesive layer 21 of the intermediate sheet C is brought into contact with and adhered to the exposed surface.

### EXAMPLES

The present disclosure will be explained below more specifically by referring to Examples.

### <Adjustment Method of Expanded Graphite Rolled Sheet>

Scale-like graphite obtained by immersing 100 weight parts of natural graphite in approximately 15 weight parts of mixture in which potassium permanganate was dissolved in concentrated sulfuric acid was heated to approximately 900° C., expanded graphite expanded to approximately 150 cm³/g in a volume ratio was press-molded so as to obtain the expanded graphite having density of approximately 1.5 g/cm³. From the aforementioned expanded graphite, impurities were further removed so as to obtain the expanded graphite having density of approximately 1.7 g/cm³. This was further rolled so as to obtain film-shaped expanded graphite rolled sheets having thicknesses of 0.127 mm, 0.106 mm, 0.076 mm, 0.051 mm, and 0.040 mm. They were measured by a thermos-wave analyzer capable of measuring a thermal diffusion coefficient in a planar direction, and the thermal diffusion coefficients were 4×10⁻⁴ m²/s, 4×10⁻⁴ m²/s, 4×10⁻⁴ m²/s, 3×10⁻⁴ m²/s, and 3×10⁻⁴ m²/s, respectively.

### <Adjustment Method of Carbonized Graphite Sheet>

A commercial polyimide film (manufactured by Kaneka Corporation, thickness of Apical AH of 25, 50, 75, 125, and 225 μm) was sandwiched by graphite plates and its temperature was raised to 1000° C. under a nitrogen atmosphere by using an electric furnace, it was subjected to heat processing for 1 hour at 1000° C., and carbonization processing (carbonization) was executed so as to obtain a carbonized film, and the film was held in a cuboid graphite container in a state of being sandwiched by a plate-shaped smooth graphite from above, the container was covered by carbon powders having coke as a main component and heated to 3000° C. not by atmospheric heating but by applying a DC voltage to the container and the entire carbon powder so as to fabricate graphite films each having a thickness of 0.040 mm and 0.025 mm. They were measured by the thermos wave analyzer capable of measuring the thermal diffusion coefficient in a planar direction, and the thermal diffusion coefficients were both 1×10⁻³ m²/s.

### <Fabricating Method of Silicone Adhesive Layer>

A coating liquid (Solid content 12 mass %) prepared by adding 15 mass parts of a mixed solvent (6:4 in a mass ratio) of toluene and methylethylketone and 0.1 mass parts of platinum catalyst [manufactured by Shin-Etsu Chemical Co., Ltd.: Product name “PL-50T”] to 10 mass parts of addition type organopolysiloxane [manufactured by Shin-Etsu Chemical Co., Ltd: Product name “KS-847H”; Solid content 30 mass %] made of organodimethylpolysiloxane having a vinyl group as an alkenyl group and organohydrogenpolysiloxane was applied to two types of polyester films 22 having a thickness of 12 μm and a thickness of 20 μm [Polyethylene terephthalate film manufactured by Teijin DuPont Films Limited: Product name “G2”] by using a Meyer bar #3, respectively, dried for 60 seconds at 160° C., and the silicone adhesive layer 23 made of a silicone elastomer and having slight tackiness was formed on the polyester film 22.

Regarding the coating liquid, the silicone adhesive layer 23 having a thickness of 20 μm was formed by applying in an application amount of 1.0 g/m², and an application amount of ¼ thereof was applied so as to form the silicone adhesive layer 23 having a thickness of 5 μm.

### <Fabricating Method of Acrylic Adhesive Layer>

To 55 mass parts of a resin liquid in which an acrylic monomer and an acrylic polymer were mixed, 5 mass parts of a hydrogenated rosin [manufactured by Arakawa Chemical Industries, Ltd. Product name “KE311”] was added as a tackifier and mixed, and 40 mass parts of toluene was further added and mixed until it became uniform. To this, 2 weight parts of TDI-based isocyanate modification crosslinking agent [manufactured by Nippon Polyurethane Industry Co., Ltd. Product name “Coronate L”] was added and further mixed until it became uniform. This coating liquid was applied on a release film having a thickness of 38 μm in an application amount of 10 g/m² by using the Meyer bar #3 and dried for 120 seconds at 130° C. so as to form the acrylic adhesive layer 21 having a thickness of 10 μm on the release film. Furthermore, with a half application amount, the acrylic adhesive layer 21 having a thickness of 5 μm was formed on the release film.

### <Composite Adhesive Film>

The obtained aforementioned composition was laminated by a device capable of heating with a linear pressure of 1 kg/cm so as to fabricate the composite adhesive film 11 having a structure in which the silicone adhesive layer 23 is arranged on one surface of the polyester film 22, and the acrylic adhesive layer 21 is arranged on a surface on the opposite side.

### Examples 1 to 5

The graphite sheet 10 (this graphite sheet 10 contains both the expanded graphite rolled sheet and carbonized graphite sheet) manufactured by the aforementioned process and the composite adhesive film 11 were subjected to vacuum heating press so as to obtain the heat diffusion sheet 2 in which the acrylic adhesive layer 21 is in contact with and fixed to the graphite sheet 10.

This heat diffusion sheet 2 is a laminated body, and the heat diffusion sheet 2 (Examples 1 and 4) having 25 μm of a polyester film and the heat diffusion sheet 2 (Examples 2, 3, and 5) having 12 μm of the polyester film were fabricated.

### Comparative Examples 1 and 2

Instead of the composite adhesive film 11 used in the present disclosure, a double-sided adhesive sheet (“commercial product 1”) not containing a thermally conductive material and having an acrylic adhesive layer formed on the both surfaces was adhered as the composite adhesive film to the one surface of the graphite sheet 10 so as to fabricate the heat diffusion sheet. This double-sided adhesive sheet has 10 μm of the acrylic adhesive layer formed on the graphite sheet side and the object to be adhered side in the Comparative example 1, while in the Comparative example 2, 30 μm of the acrylic adhesive layer is formed on the graphite sheet side and the object to be adhered side, and the thicknesses of the graphite sheet layers are 106 μm and 127 μm, respectively.

Because the acrylic adhesive layer is adhered to the object to be adhered, detachability is poor.

### Comparative Example 3

On a polyester film having a thickness of 12 μm, an acrylic adhesive layer with a thickness of 10 μm and a silicone adhesive layer with a thickness of 20 μm were formed, and the acrylic adhesive layer was adhered to a graphite sheet having a thickness of 127 μm. For the silicone adhesive layer, a silicone adhesive sheet manufactured by Dexerials Corporation [Product name T4082S] was used.

The thickness of the silicone adhesive layer is larger than that of the polyester film, peeling is difficult, and the polyester film is deformed in some cases and thus, workability is poor.

### Comparative Example 4

On the graphite sheet manufactured in the aforementioned process, the coating liquid for the aforementioned silicone adhesive layer was applied/dried so as to form the silicone adhesive layer 23, and the heat diffusion sheet was obtained. A composite adhesive film was not used.

### <Measurement Test>

The following tests were conducted for the heat diffusion sheets of the Examples 1 to 5 and the Comparative examples 1 to 4.

Thermal Diffusion Coefficient Test

The heat diffusion sheet was cut out by a punch to 15 mm×15 mm, and the thermal diffusion coefficient when an equilibrium state was reached under a temperature of 25° C. was calculated by using a thermal diffusion coefficient measuring device (thermos wave analyzer TA3: manufactured by Bethel, Co., Ltd.). The thermal diffusion coefficient is more preferable as it is higher, and at least 10⁻⁴ m²/s is desirable.

Detachability Test

The heat diffusion sheet was laminated on a glass plate (soda lime glass) with a linear pressure of 1 kg/cm and after 7 days have elapsed at a room temperature, it was checked whether the composite adhesive sheet could be detached from the glass plate. Furthermore, it was checked whether detachment residues remained on the surface of the glass plate after the detachment.

Adhesion Reliability Test

The heat diffusion sheet was laminated on a glass plate (soda lime glass) with a linear pressure of 1 kg/cm and input in an atmospheric constant temperature and humidity oven adjusted to 60° C. and 75% RH, and an appearance after 1000 Hr have elapsed was checked.

### <Test Results>

Measurement Values

Results of each test are illustrated in the following

Tables 1 and 2.

TABLE 1
measurement results or heat diffusion sheets in Examples 1 to 5

| | Example 1 | Example 2 | Example 3 | Example 4 | Example 5 |
|---|---|---|---|---|---|
| Thickness of graphite sheet (μm) | 76 | 51 | 40 | 40 | 25 |
| | (Expanded | (Expanded | (Expanded | (Carbonized | (Carbonized |
| | graphite) | graphite) | graphite) | graphite) | graphite) |
| Thickness of acrylic adhesive | 10 | 5 | 5 | 5 | 5 |
| layer (μm) | | | | | |
| Thickness of polyester film (μm) | 25 | 12 | 12 | 25 | 12 |
| Thickness of silicon adhesive | 20 | 5 | 5 | 5 | 5 |
| layer (μm) | | | | | |
| Peeling strength of silicone adhesive | 0.7 | 0.6 | 0.5 | 0.5 | 0.3 |
| laver (N/cm) | | | | | |
| Total thickness of composite | 55 | 22 | 22 | 35 | 22 |
| adhesive film (μm) | | | | | |
| Thickness of polyester film (μm)/ | 1.25 | 2.4 | 2.4 | 5 | 2.4 |
| thickness or silicone adhhesive | | | | | |
| layer (μm) | | | | | |
| Thermal diffusion coefficient (m²/s) | 1 × 10⁻⁴ | 2 × 10⁻⁴ | 2 × 10⁻⁴ | 8 × 10⁻⁴ | 8 × 10⁻⁴ |
| Detachability | A (Favorable) | A (Favorable) | A (Favorable) | A (Favorable) | A (Favorable) |
| Adhesion reliability | A (Favorable) | A (Favorable) | A (Favorable) | A (Favorable) | A (Favorable) |

TABLE 2
Measurement results of heat diffusion sheets in Comparative examples 1 to 4

| | Comparative | Comparative | Comparative | Comparative |
|---|---|---|---|---|
| | example 1 | example 2 | example 3 | example 4 |
| Thickness of graphite sheet (μm) | 106 | 127 | 127 | 127 |
| | (Expanded | (Expanded | (Expanded | (Expanded |
| | graphite) | graphite) | graphite) | graphite) |
| Thickness of acrylic adhesive layer (μm): | 10 | 30 | 10 | — |
| graphite sheet side | | | | |
| Thickness of silicone adhesive layer (μm): | — | — | — | — |
| graphite sheet side | | | | |
| Thickness of polyester film (μm) | 12 | 12 | 12 | — |
| Thickness of silicone adhesive layer (μm): | — | — | 20 | 20 |
| object to be adhered side | | | | |
| Thickness of acrylic adhesive layer (μm): | 10 | 30 | — | — |
| object to be adhered side | | | | |
| Peeling strength of silicone adhesive layer | 5 | 10 | 4 | 5 |
| on the object to be adhered side or acrylic | | | | |
| layer (N/cm) | | | | |
| Total thickness of composite adhesive film | 32 | 72 | 42 | 20 |
| (μm) | | | | |
| Thickness of polyester film (μm)/thickness | 1.2 | 0.4 | 0.6 | — |
| of silicone adhesive layer (μm): object | | | | |
| to be adhered side | | | | |
| Themal diffusion coefficient (m²/s) | 1 × 10⁻⁴ | 6 × 10⁻⁵ | 1 × 10⁻⁴ | 2 × 10⁻⁴ |
| Detachability | B (Possible) | C (Defective) | B (Possible) | C (Defective) |
| Adhesion reliability | C (Defective) | A (Favorable) | A (Favorable) | A (Favorable) |

(“—” indicates that the layer is not provided. )

Evaluation of Detachability

The following evaluations are indicated in columns for detachability in Tables 1 and 2:

A Favorable: Peelable off the glass plate with a small force, and residues do not remain on the surface peeled off the glass plate

B Possible: Peelable off the glass plate anyway. Residues do not remain on the surface peeled off the glass plate, but deformation of the polyester film occurs.

C Defective: Peeling off the glass plate requires a considerable force. Residues remain on the surface peeled off the glass plate.

Evaluation of Adhesion Reliability

The following evaluations are indicated in columns for adhesion reliability in Tables 1 and 2:

A Favorable: No occurrence of floating at all, and end portions cleanly adhere.

B Possible: Substantially no occurrence of floating but the end portion is partially raised.

C Defective: Occurrence of floating is found, and an end portion is raised.

### REFERENCE SIGNS LIST

2 heat diffusion sheet
10 graphite sheet
11 composite adhesive film
21 acrylic adhesive layer
22 polyester film
23 silicone adhesive layer

1. A heat diffusion sheet comprising:
a graphite sheet, and
a composite adhesive film arranged on a surface of the graphite sheet,
wherein a thickness of the graphite sheet is in a range of at least 20 μm and less than 80 μm;
wherein a thickness of the composite adhesive film is within a range of at least 20 μm and at most 100 μm, and
the composite adhesive film comprises:
an acrylic adhesive layer arranged on the graphite sheet and not containing a thermally conductive material;
a polyester film arranged on the acrylic adhesive layer and having a thickness within a range of at least 5 μm and at most 30 μm; and
a silicone adhesive layer arranged on the polyester film, thinner than the polyester film, having a thickness within a range of at least 2 μm and at most 25 μm, not containing a thermally conductive material, and having a peeling strength of at least 0.005 N/cm and at most 1.0 N/cm.

2. A heat diffusion sheet comprising:
a graphite sheet, and
a composite adhesive film arranged on a surface of the graphite sheet,
wherein a thickness of the graphite sheet is in a range of at least 20 μm and less than 80 μm;
the composite adhesive film comprises:
an acrylic adhesive layer arranged on the graphite sheet and not containing a thermally conductive material;
a polyester film arranged on the acrylic adhesive layer and having a thickness within a range of at least 5 μm and at most 30 μm; and
a silicone adhesive layer arranged on the polyester film, thinner than the polyester film, having a thickness within a range of at least 2 μm and at most 25 μm, not containing a thermally conductive material, and having a peeling strength of at least 0.005 N/cm and at most 1.0 N/cm, and
wherein a total value of a thickness of the acrylic adhesive layer, the thickness of the polyester film and the thickness of the silicone adhesive layer is within a range of at least 12 μm and at most 70 μm.
